(19) United States
(12) Patent Application Publication
(10) Pub. No.: US 2007/0146024 A1
(43) Pub. Date: Jun. 28, 2007

(54) Mixed-signal thermometer filter, delay locked loop and phase locked loop

(76) Inventor: Gordon John Allan, Ottawa (CA)

Correspondence Address: SMART & BIGGAR;P.O. BOX 2999, STATION D, 900-55 METCALFE STREET, OTTAWA, ON, K1P5Y6, CA

(21) Appl. No.: 10/568,279

(22) PCT Filed: Jul. 7, 2005
(86) PCT No.: PCT/CA05/01060

§ 371 Date: Feb. 15, 2006

(30) Foreign Application Priority Data
Jul. 8, 2004 (CA) 2474111

(51) Int. Cl. H03L 7/06

(52) U.S. Cl. 327/156

(57) ABSTRACT

Circuits for implementing a thermometer code in a mixed-signal fashion are provided. Each of a set of outputs can be digital or analog in a transition region. The mixed signals can be used to control delay elements in a delay line for application in DLLs or PLL or clock de-skew circuits, or can be used to control voltage controlled oscillators. Two sets of driver elements are connected to the set of mixed signal outputs and in a first control state, one of the sets drives the mixed-signal outputs sequentially to off states, while in another control state, the other of the sets drives the mixed-signal outputs sequentially to on states. Any mixed-signal that is not completely driven to its on or off state will generate an analog output.

### FIELD OF THE INVENTION

The invention relates to circuits that manipulate the delay or frequency of signals travelling within a circuit or system.

### BACKGROUND OF THE INVENTION

Delay-locked loops (DLLs) and phase-locked loops (PLLs) are commonly used to manipulate the delay through a circuit to match some reference period. Such circuits can then be easily extended to produce output clocks at rational multiples of a reference frequency. DLLs and PLLs are found in clock distribution networks, on-chip clock generators, synchronizers, clock-data-recovery systems, clock multipliers, de-skew circuits, etc. These circuits can be implemented in analog or digital form, where the primary complexity of the design is within the loop-filter which stabilizes the delay as a function of speed-up (up) or slow-dn (dn) signals from a phase-error detector.

In analog implementations, the up/dn signals from a phase-detector feed a charge-pump that adds or removes charge from a large capacitance while the error signal is asserted. The voltage on the capacitance then adjusts the delay through the circuit to compensate and reduce the phase error. For singular up/dn signals, the voltage should have negligible change and thus it requires many subsequent commands to appreciably affect the delay. These analog designs are limited by the noise inherent in the system, and by their relative tolerance to this noise. As supply voltages are lowered in modern circuits, the allowable range of the control voltage, and thus the noise tolerance, is also reduced. Elaborate measures must be taken in attempts to compensate (eg. voltage regulators, higher order filters, more complex current sources, dual-gain VCOs, etc.) Other drawbacks with analog DLLs and PLLs include the relatively large lock-time, area, power, and design time requirements of the loop filter and delay-line or oscillator.

In digital implementations, whenever an up/dn signal is asserted, it increments or decrements a counter within a digital control loop. Unlike analog charge-pumps, the width of the up/dn signal is not taken into account, and thus small and large phase errors are treated equally. The results from the counter are then digitally filtered and decoded into a large number of control bits (either logical 1 or 0) that abruptly switch the delay of the circuit. This abrupt switching leads to quantization induced jitter that degrades the quality of the output signal and can lead to functional errors. Furthermore, the accuracy of digital implementations is typically lower than analog ones due to an increased dead-zone (in response to the phase detector) and lower output resolution. Digital filters also suffer from decreased stability, and a relatively large power and area overhead. Digital versions, however, enjoy simpler design and integration than their analog counterparts. Another advantage of digital architectures is that the delay of the circuit is uniquely controlled by the digital control string which is usually stored in a set of registers. Since the lock-state of the circuit is in memory, portions of the system can be powered down without loss of timing alignment.

Hybrid solutions exist that use digital control loops for coarse locking and analog control loops for fine adjustment. This allows for relaxation of both the digital and analog filter requirements, but each of the two sub-loops still retain their inherent disadvantages of power, area, and integration inefficiency. For such hybrid solutions, the outer digital control loop normally requires only a little filtering, and thus the complexity of such systems is normally dominated by the inner analog control loop.

### SUMMARY OF THE INVENTION

According to one broad aspect, the invention provides a circuit comprising: a plurality of mixed-signal outputs; a first set of driving elements connected together in sequence each having a respective output connected to a respective one of the mixed-signal outputs, the first set of driving elements having a first driving element and having a last driving element; a second set of driving elements connected together in sequence each having a respective output connected to a respective one of the mixed signal outputs in an order opposite to an order of connection of the first set of driving elements to the mixed signal outputs, the second set of driving elements having a first driving element and a last driving element; wherein while in a first control state the first set of driving elements drives each of the mixed-signal outputs towards a respective off state sequentially in a direction from the first driving element of the first set towards the last driving element of the first set such that any mixed-signal output that is driven only partially towards its respective off state maintains an analog value; and wherein while in a second control state the second set of driving elements drives each of the mixed-signal outputs towards a respective on state sequentially in a direction from the first driving element of the second set towards the last driving element of the second set such that any mixed-signal output that is driven only partially towards its respective on state maintains an analog value; wherein while in a third control state each mixed-signal value maintains its respective value.

According to another broad aspect, the invention provides a circuit implemented method comprising: in a first control state, driving each of a set of mixed-signal outputs towards a respective off state sequentially from a first mixed signal output towards a last mixed-signal output such that any mixed-signal output that is driven only partially towards its respective off state maintains an analog value; and in a second control state, driving the mixed-signal outputs towards a respective on state sequentially from the last mixed-signal output towards the first mixed-signal output such that any mixed-signal output that is driven only partially towards its respective on state maintains an analog value.

According to another broad aspect, the invention provides a circuit comprising: at least one control input defining at least a first control state and a second control state; a plurality of mixed-signal outputs each characterized by a respective on state, a respective off state, and a respective analog range; a set of circuit elements connected to cause sequential transitions of any mixed-signal output that is in a respective off state or in the respective analog range towards a respective on state during a first control state, and to cause sequential transitions of any mixed-signal output that is in a respective on state or in the respective analog range towards a respective off state during a second control state.

According to another broad aspect, the invention provides a method for dynamically determining if a particular output of a set of mixed-signal outputs representing a mixed signal code is outputting an analog value, the method comprising: receiving at least one neighbouring mixed-signal outputs; determining if the neighbouring mixed-signal outputs are consistent with the particular mixed-signal output being an analog value for the mixed-signal code.

According to another broad aspect, the invention provides a method for processing a set of mixed-signal outputs, the method comprising: detecting when a particular mixed-signal output has reached a digital state; upon detecting that a particular mixed-signal output has reached a digital state, securing the particular mixed-signal output to an appropriate reference.

### BRIEF DESCRIPTION OF THE DRAWINGS

Preferred embodiments of the invention will now be described with reference to the attached drawings in which:

FIG. 1 is a schematic diagram of a DLL configuration employing mixed signals;

FIG. 2A is a schematic diagram of another DLL configuration providing an embodiment of the invention;

FIGS. 2B and 2C are control string examples for tri-state buffers and inverters respectively;

FIG. 2D is a set of example circuits for connecting delay to each mixed-signal output;

FIG. 3 shows an example of signals with logic OFF re-biasing;

FIG. 4 is a circuit diagram of circuits for re-biasing logic OFF;

FIG. 5 is a simplified model of a section of a thermometer filter;

FIG. 6 is a circuit diagram of circuits for re-biasing logic ON;

FIG. 7 is a block diagram of optional features for inclusion prior to the thermometer filter;

FIGS. 8A and 8B are circuit diagrams of circuits for stabilizing digital values;

FIG. 9A is a gate-level representation of a 4-“bit” thermometer filter;

FIG. 9B is a transistor-level representation of the thermometer filter of FIG. 9A;

FIG. 10A is an example of switching logic for sharing filter stages between all N stages of a thermometer filter;

FIG. 10B is an example of state storage and more practical switching using transmission gate logic;

FIG. 11 is a block diagram of a thermometer filter used in a PLL synthesizer configuration;

FIG. 12 is a block diagram of a thermometer filter used in a DLL synthesizer configuration;

FIGS. 13 and 14 are block diagrams of a thermometer filter used in a DLL de-skew circuit configuration;

FIG. 15 is a flowchart of a method of identifying analog outputs of a set of mixed-signal outputs; and

FIG. 16 is a flowchart of a method of identifying digital outputs of a set of mixed-signal outputs.

### DETAILED DESCRIPTION OF THE PREFERRED EMBODIMENTS

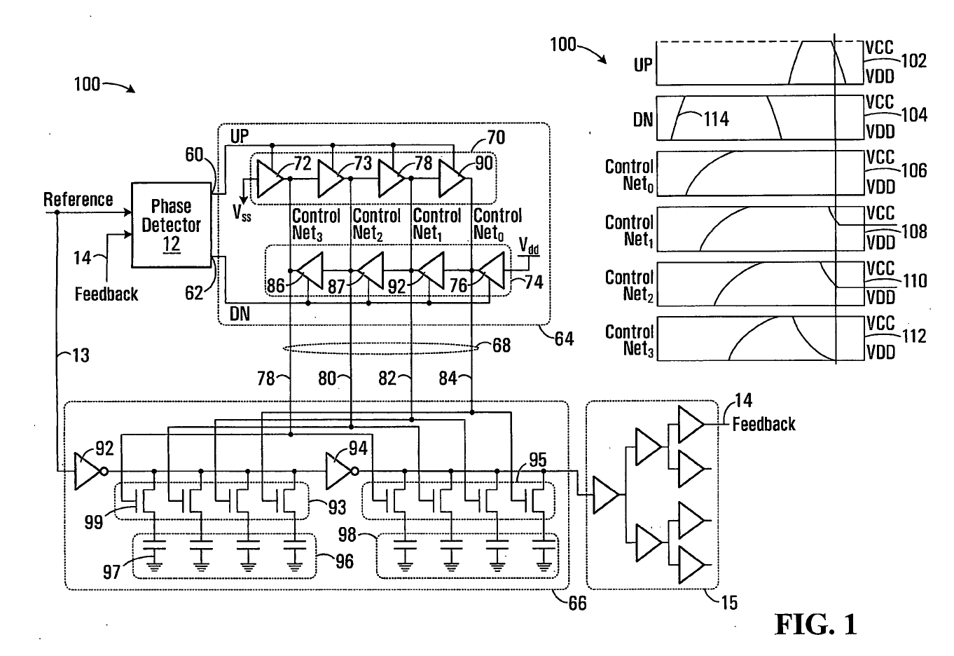

Referring first to FIG. 1, shown is a particular delay-locked loop circuit provided by an embodiment of the invention connected in the form of a DLL clock de-skew circuit. A phase-error detector 12 having up and down outputs 60,62 is connected to a mixed-signal thermometer filter 64, hereinafter referred to thermometer filter 64. The phase detector 12 is connected to receive a reference input 13 and a feedback input 14. The reference input 13 is also input to a mixed-signal variable delay line 66. The thermometer filter 64 is connected through a plurality of interconnections 68 to the mixed-signal variable delay line 66 as described in further detail below. The output of the mixed-signal variable delay line 66 is connected to a buffer tree 15 which drives the circuit loads (e.g. flip-flops) and generates as one of its outputs the feedback signal 14. It is intended that the loads driven by the buffer tree 15 should all receive the signal simultaneously to the feedback signal 14, and that this signal be aligned exactly with an edge of the periodic reference input 13. The thermometer filter 64 connects the up output 60 of the phase detector 12 to the control input of each of a first set 70 of tri-state buffers 72,73,78,90. The input of the first tri-state buffer 72 of the set of the tri-state buffers 70 is shown connected to logic 0 (Vₛₛ) The output of each of the tri-state buffers 70 is connected in sequence to the input of the next tri-state buffer in the set with the exception of the last tri-state buffer of the set with the set being shown connected from left to right in the illustrated embodiment. Each tri-state buffer has an input and an output and a control input. The input is driven across to the output so long as the control input is activated. In other words, if the control input is active and there is a logic 0 input, the tri-state buffer drives its output towards a logic 0 or drives a logic 1 input to output towards a logic 1. Once the control input is de-activated, the output of the tri-state buffer maintains its value at that point.

Similarly, the down output 62 of the phase detector 12 is connected to the control input of each of a second set 74 of tri-state buffers 76,92,87,86. The first tri-state buffer 76 in the second set 74 is connected to a logic 1 (V_{dd}). Each of the tri-state buffers in the second set 74 has an output connected to the input of the next tri-state buffer in the set with the exception of the last tri-state buffer in the second set with the set shown being connected from right to left in the illustrated embodiment.

In the illustrated example, each of the two sets of tri-state buffers 70,74 each consist of four tri-state buffers. The output of the first tri-state buffer 72 of the first set 70 is connected to the output of the last tri-state buffer 86 of the second set 74, and this interconnected output is output from the thermometer filter 64 on interconnection 78. Similarly, the output of the second tri-state buffer 73 of the first set 70 has an output connected to the output of the second to last tri-state buffer 87 of the second set 74, and this is output on interconnection 80. The third tri-state buffer 78 of the first set 70 has an output connected to the output of the second tri-state buffer 92 of the second set 74 and these outputs are connected to interconnection 82. Finally, the output of the last tri-state buffer 90 of the first set 70 has its output connected to the output of the first tri-state buffer 76 of the second set 74, and this is output on interconnection 84. More generally, any appropriate equal number of tri-state buffers can be included in each of the two sets. The number of interconnections in the set of interconnections 68 is equal to the number of tri-state buffers in the two sets.

Each pair of interconnected outputs is connected to the respective interconnection 78,80,82,84 that is capable of sustaining a charge, and therefore a voltage, the voltages hereinafter referred to as control net₃, control net₂, control net₁, and control net₀.

The mixed-signal variable delay line 66 is shown to include two inverters 92,94. More generally, any appropriate number of inverters or drivers might be included. After each inverter 92,94 there is a respective set of capacitances 96,98 interconnected to the delay line through respective sets of transistors 93,95. The on/off state of each of these transistors is controlled by signals emanating from interconnections 68 from the thermometer filter 64. Depending upon the signal on a given one of the interconnections 68, the corresponding capacitances in the sets of capacitances 96,98 are either completely disconnected from the delay line 66, completely connected to the delay line, or partially connected to the delay line as will be described in further detail below.

In one embodiment, the capacitances 96,98 are not separately implemented components, but rather are simply the capacitances that result from leaving the source of each of the transistors 93,95 physically unconnected. Left unconnected, the source of each of the transistors 93,95 will naturally form a small parasitic capacitance to the substrate. In another embodiment, the drain and source of the transistors 93,95 are both connected to the load, and the voltage controlled capacitance of each of the transistors functions as the capacitance that is switched in or out.

In operation, the phase detector 12 generates either an up or down output 60,62 that reflects the difference in phase between the reference signal 13 and the feedback signal 14. The reference signal is a clock signal as is the feedback signal 14. In the event the reference signal is earlier than the feedback signal 14, i.e. the phase error is positive, the up output 60 is activated for a duration equal to the phase error. Similarly, if the feedback signal is earlier, the down output 62 is activated for a period of time equal to the phase error. To illustrate the operation of the thermometer filter 64, consider the set of plots generally indicated at 100 in FIG. 1. Shown is a set of example plots for an up signal 102, a down signal 104, control net₀ 106, control net₁ 108, control net₂ 110, and control net₃ 112. In the illustrated example, it is assumed that the phase-detector 12 first asserts the down signal 62 as shown by rising edge 114 in plot 104. This begins a sequence that charges the control nets from right to left by setting the corresponding outputs of the second set of tri-state buffers 74 to high states. During this time, the control input to the first set of buffers 70 is off and as such, the second set of buffers 74 has control over charging the control nets. With the down signal 62 asserted, the second set of buffers 74 is enabled, and the first tri-state buffer 76 begins to drive the logic 1 from its input to its output. As such, the output of the first tri-state buffer 76 transitions from maintaining a logic 0 to a logic 1 and this charges control net₀ as indicated in plot 106; sometime later, once the output of the first tri-state buffer 76 is high enough, this output starts to drive the output of the second tri-state buffer 92 from a logic 0 to a logic 1 and this charges control net₁ as indicated in plot 108. Slightly later, the third tri-state buffer 87 transitions from logic 0 to a logic 1, and this charges control net₂ as indicated in plot 110 and yet later still the fourth tri-state buffer 86 transitions from logic 0 to logic 1, and this charges control net₃ indicated in plot 112. At this point, all of the second set of tri-state buffers are driving a logic 1 and the control nets are fully charged. When the down signal 62 is de-asserted, the control nets maintain their charge at logic 1.

Sometime later in the illustrated example, the up signal 60 is then asserted by the phase detector 12 as indicated in plot 102. There is a logic 0 connected to the input of the first buffer 72. This begins a sequence of discharging the control nets from left to right by setting the corresponding outputs of the first set of tri-state buffers 70 to low states. During this time, the control input to the second set of buffers 74 is off and as such, the first set of buffers 70 has control over discharging the control nets. As such, as the output from the first tri-state buffer 72 transitions from a 1 to a 0, control net₃ decreases from fully charged to uncharged as indicated in plot 112. A little later, the output of the first tri-state buffer 72 drives the second tri-state buffer 73 to decrease control net₂. However, in the illustrated example the up signal is not asserted long enough for the complete discharge of control net₂. Once the up signal is not asserted anymore, the tri-state buffers are de-activated, and essentially just maintain their current state. Plot 110 shows control net₂ partially discharged. Similarly, control net₁ is also shown even less partially discharged in plot 108. The values of control net₁ and control net₂ can be considered “analog” in nature, while the remaining control nets (only control net₀ and control net₃ in the example) are digital, hence the reference to the thermometer filter 64 as a “mixed-signal” thermometer filter.

The control nets 68 maintain their value while neither of the up or down signals are asserted. The application of the up or down signals from the phase detector will cause the values on the control nets to slowly vary and shift. Persistent application of either of these signals will cause the thermometer filter to its limit at 1111 or 0000. However, in normal operation, the control nets collectively will settle to an intermediate state where the majority of the nets are at their digital extremes and a small number maintain analog values fluctuating around an analog bias point, somewhere between V_{dd} and Vₛₛ. The set of mostly digital values and a few analog values will be referred to as a “control string”.

This control string of mostly digital bits is then used to manipulate the delay through the mixed signal variable delay line 66. Via interconnections 68, each control net is connected to at least one of the transistors in the sets 93,95. As a particular control net voltage increases, that switches on (or partially on) the connected transistor in each set of transistors, and extra capacitance is effectively exposed to the loaded net thus increasing the delay through the delay line 66. As a control net voltage lowers, the connected transistors are switched off (or partially off), and the capacitance has less effect on the load and the delay through the mixed-signal variable delay line 66 decreases.

The transistors that are connected to logic 1 will have their capacitances completely exposed to the delay line; the transistors connected to logic 0 will have their capacitance completely unconnected from the delay line; finally, the transistors connected to an analog value will have their capacitances partially exposed to the delay line. For example, control net₃ (interconnection 78) is shown connected to transistor 99 so as to control whether, none, some, or all of the capacitance 97 is effectively exposed to the delay line 66.

The effect of the thermometer filter 64 is that the up signal drives zeros from left to right through the first set tri-state buffers 70 while the down signal drives ones from right to left through the second set of tri-state buffers 74. The left to right driving of zeros takes place only so long as the up signal is asserted. Similarly, the right to left driving of ones only takes place during the assertion of the down signal. Thus, the relative length of time that the buffers are being driven right to left or left to right respectively is a function of how long the up or down signals respectively are activated. Typically, once the error between the reference signal 13 and the feedback signal 14 becomes very small, a more or less stable control string will be realized in which the control nets have a sequence of logic 0s, 1, 2 or 3 analog values, and then a sequence of one or more logic 1s.

A very specific method of switching in and out capacitances has been shown in the embodiment of FIG. 1. With the illustrated embodiment, the voltages on interconnections 68 is used to switch in or out a capacitance associated with each of transistors in the sets 93,95, or to switch in and out extra capacitances between the transistors 98 and the substrate (not shown). In another embodiment, the voltages on interconnections 68 can be used to adjust the drive strength of each of the inverters/delay elements in the delay line 66. In yet another example, each of the interconnections 68 is connected to a varactor (which may for example be used in an LC oscillator) to adjust the capacitance that is switched into the circuit between a minimum and a maximum and not excluding intermediate values.

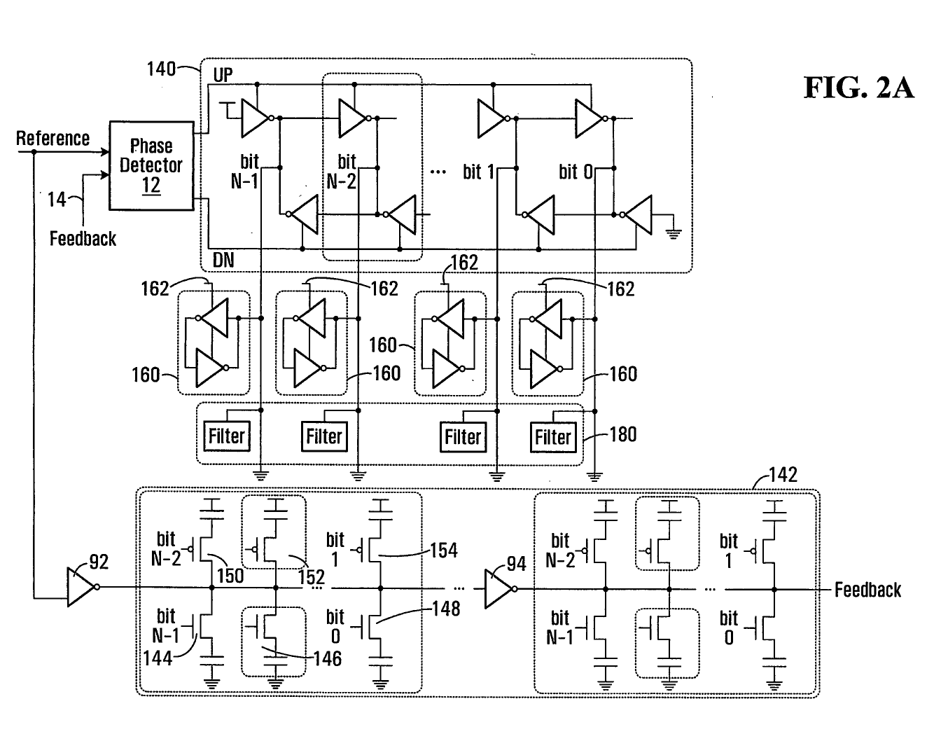

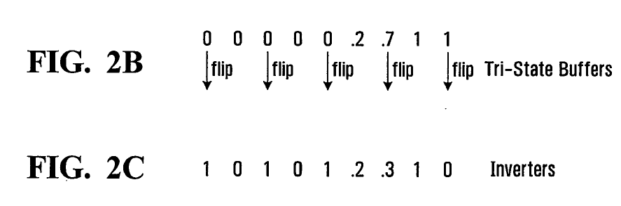

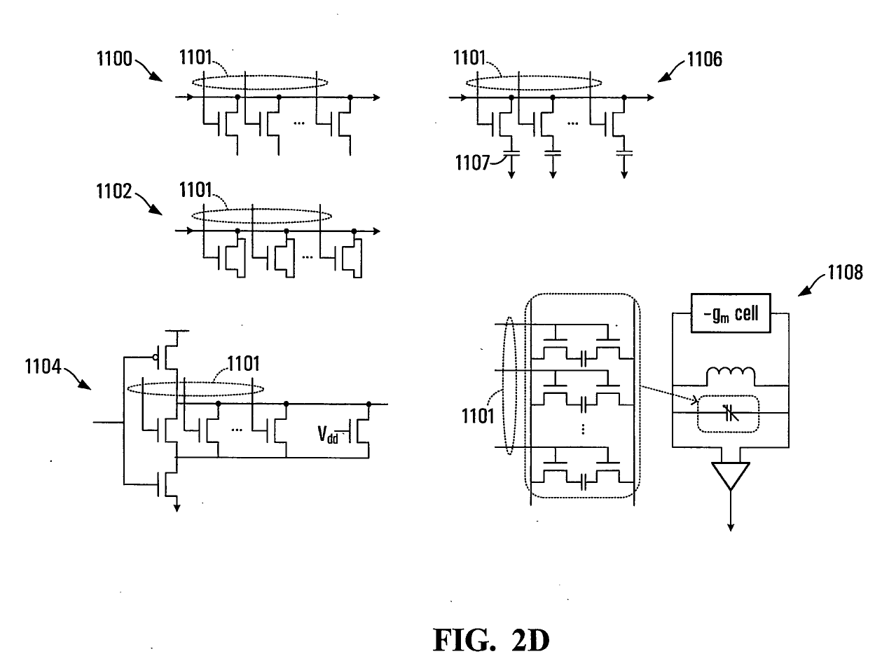

FIG. 2D shows several different ways the control voltage can be used to introduce delay in a delay element or effect oscillation frequency where in each case, the mixed-signal outputs of the thermometer filter are indicated at 1101. In the first example, generally indicated at 1100, one lead of each transistor is simply left unconnected, and the resulting capacitance between that and the substrate is what is connected in or out of the delay line. In the second example, generally indicated at 1102, the transistor source and drain are connected together, such that it is the capacitance of the transistor per se that is switched in and out. In the third example, generally indicated at 1104, a variable drive transistor arrangement is employed. In the fourth example, generally indicated at 1106, a respective capacitor 1007 is connected at the output of each transistor, this being the design used in the examples of FIGS. 1 and 2A. In the fourth example, generally indicated at 1008, variable oscillation frequency is realized by connecting a capacitance between two transistors both driven by the mixed-signal outputs.

More generally, it is to be understood that once the mixed-signal control string is generated, any appropriate mixed signal delay line or oscillator can be employed that adds or removes a discrete amount of delay for each digital value in the control string, and adds an analog/variable amount of delay for each analog value in the control string.

The embodiment of FIG. 1 employs tri-state buffers in the thermometer filter 64. In another embodiment, rather than tri-state buffers, inverters are employed. Inverters behave similar to the tri-state buffers in the sense that they have a control input that either activates them or de-activates them. However, the output of an inverter is the logical opposite of the input. For analog values of the input (between logic 1 and 0), the output will begin to respond once the input has moved sufficiently away from V_{dd} or Vₛₛ to turn on the internal transistors. Once this has happened, the logical output can be approximated as Vout=1−Vin. An example of a DLL circuit that employs inverters rather than tri-state buffers is shown in FIG. 2A. This figure is similar to FIG. 1 in that there is an asynchronous dual direction mixed-signal thermometer filter 140 (hereinafter simply thermometer filter 140) that is similar to the thermometer filter 64 of FIG. 1, but in which inverters are used rather than tri-state buffers. There is also a phase detector 12 which is the same as before, and a mixed-signal variable delay line 142 which has been modified to accommodate the fact that every second output of the thermometer filter 140 has been inverted. Thus, where the output of a nine bit tri-state buffer based thermometer filter might be as shown in FIG. 2B to consist of five logic 0s followed by analog 0.2, analog 0.7 and then two logic is, the similar output for a circuit that is built using inverters would be as shown in FIG. 2C and consists of logic 1, logic 0, logic 1, logic 0, logic 1, analog 0.2, analog 0.3, logic 1, logic 0. This is the result of every second one of the bits/analog values shown in FIG. 2B being inverted.

For the tri-state buffer based arrangement of FIG. 1, a logic 1 output by the buffer has the effect of turning on one of the capacitances in the mixed-signal variable delay line and increasing the delay accordingly. With the inverter-based solution, for every second output, a logic 1 will need to switch in the capacitance (more generally increase delay), while for every other output a logic 0 will need to switch in the capacitance (more generally increase delay). An example of how this can be achieved is shown with the mixed-signal variable delay line 142 of FIG. 2A, where N is assumed to be an odd integer in the illustrated example. The odd outputs (i.e., the outputs that have not been inverted) are shown connected to PMOS transistors, and the even outputs, i.e., those that have been inverted, are connected to NMOS transistors. More specifically, referring to the outputs of the thermometer filter 140 as bit N-1, . . . , bit 0 from left to right, (a “bit” being a 1, 0, or analog value) it can be seen that bit N-1 is connected to NMOS transistor 144, bit N-3 is connected to NMOS transistor 146 and so on down to bit 0 which is shown connected to NMOS transistor 148. Bit N-2 is shown connected to PMOS transistor 150, bit N-4 is shown connected to PMOS transistor 152, and finally bit 1 is shown connected to PMOS transistor 154. These interconnections are shown for the capacitances connected and disconnected after the first inverter 92. Similar interconnections are shown for the delay elements following the second inverter 94. The inverted outputs that are connected to the NMOS transistors then cause a similar effect on delay as non-inverted outputs connected to PMOS transistors.

For the embodiment of FIG. 2A, again an arbitrary number of inverters or drivers can be included in the thermometer filter, and the delay line can be implemented in any suitable fashion to introduce discrete/analog delay as dictated by the control string. While implementations using inverters and tri-state buffers have been described, more generally any driver elements can be employed. Further examples of a driver element include single transition driver elements such as a single-transition tri-state buffer and a single-transition inverter, both described below.

Various modifications/alternatives will now be described. These can be applied to the inverter based implementations or the tri-state buffer based implementations.

Phase Detector Conditioning

The output from a conventional phase/frequency detector can be used to directly feed the thermometer filter. Various modifications can be made to improve performance. In some existing phase/delay locked loops, there is a so-called “dead zone” that can exist when the reference signal is very close to the feedback signal. This is because the up or down signal is asserted for a very short period of time that basically does not get processed by the circuitry that follows. Some implementations of the thermometer filter 64 and 140 may suffer from this effect. One way to deal with this is to impose a minimum duration upon the assertions included in either of the up or down outputs of the phase detector. Another approach is to assert both the up and down simultaneously for at least a minimum duration, and with a difference between the length of time that the up and down inputs 60,62 respectively are asserted set equal to the actual phase error. In this manner, the assertions are longer than the actual phase error, but the difference between these assertions, should be the same as the actual phase error. Provided that the analog up and down currents are well matched, then the overall effect will be the same as if only the direct phase error was applied.

Logic off Re-Biasing for Faster Response

Another embodiment of the invention provides another solution to dealing with the “dead zone” problem. For the up and down signals generated by the phase detector that are used to drive the two sets of tri-state buffers (or inverters), typically these would be two state signals that are either completely on or completely off, i.e., logic 1 or a logic 0. However, in accordance with this embodiment, when these signals are in the off state, the voltage is not reduced all the way down to a logic 0, but rather reduced down to a threshold voltage Vₜₕ that is just below what is necessary to start turning on the buffers. Each of the tri-state buffers or inverters typically has one or more transistors that are switched on or off by the up and down signals. By keeping the off state of these driving voltages very close to or at the threshold voltage of such transistors, even a very short duration of pulse in the up or down signal will have the chance to turn on the transistor and have an effect upon the delay that is introduced into the delay line. Because the control signals do not turn all the way off, they respond much faster to small phase corrections, thus reducing dead-zone problems.

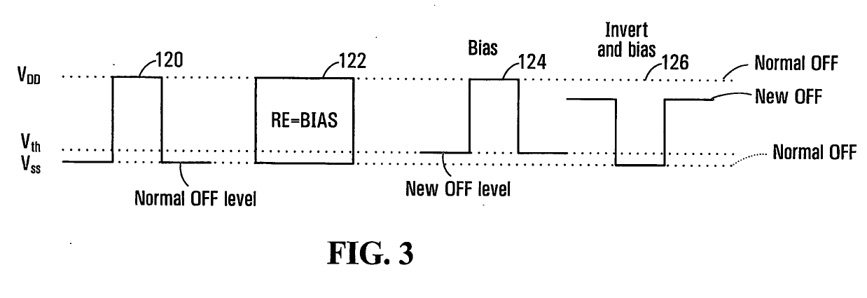

An example of re-biasing the off level generated by the phase detector 12 is shown in FIG. 3 where a pulse that might for example be generated on the up output 60 is shown generally indicated by 120. This is shown to have an off state Vₛₛ and an on state V_{dd}. After re-biasing by a re-biasing circuit 122, the shape of the pulse is as shown in 124 where the pulse now is shown to transition from a threshold voltage Vₜₕ to an on voltage V_{dd}.

In some embodiments, the thermometer filter also needs inverted versions of the up and down signals. The re-biasing circuit 122 will perform an invert and bias operation in which case the output of the re-biasing circuit 122 would be as shown generally indicated at 126. For these active-low signals, the logic ‘off’ level is normally V_{dd}. Again, to achieve faster response, the ‘off’ level for these control signals can instead be re-biased to V_{dd}-Vₜₕ.

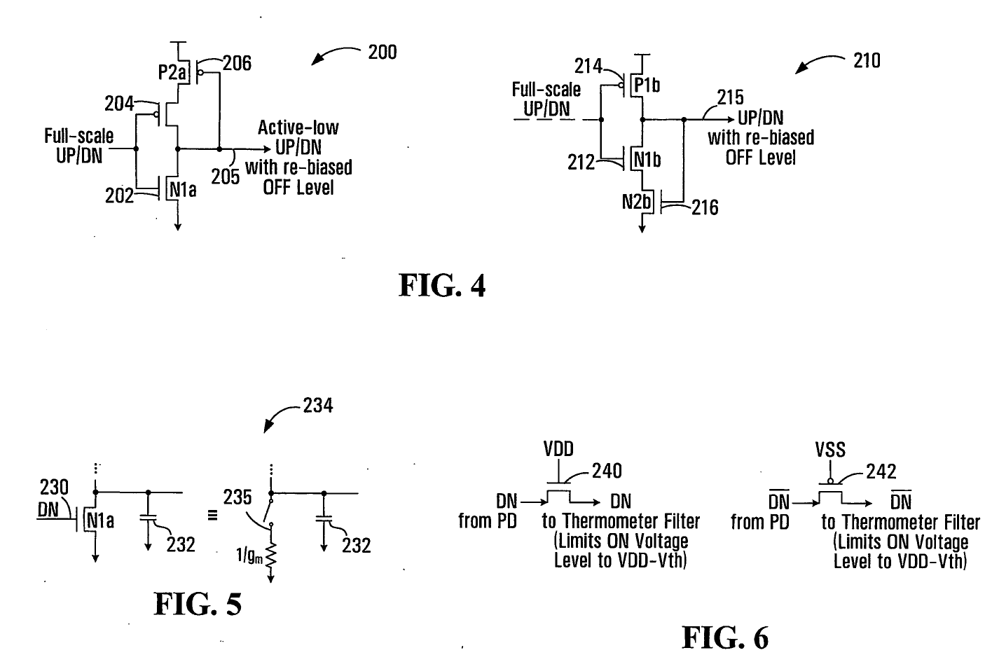

This re-biasing can be performed in a number of ways. A simple option is shown in FIG. 4. In some embodiments, rather than coupling a conventional phase-detector to these biasing circuits, the number of transistors can be reduced if these circuits are combined into one entity.

Referring now to FIG. 4, generally indicated at 200 is a circuit that re-biases the OFF level of an active-low up/down signal. The full scale up/down signal is input in a conventional manner to PMOS transistor 204, and NMOS transistor 202. However, PMOS transistor 204 is connected through additional PMOS transistor 206. The output 205 has a re-biased OFF level because the output will only be pulled up to VDD-Vth due to the additional PMOS transistor 206.

Similarly, generally indicated at 210 is a circuit that re-biases the OFF level of an active-high up/down signal. The full scale up/down signal is input in a conventional manner to PMOS transistor 214, and NMOS transistor 212. However, NMOS transistor 212 is connected through additional NMOS transistor 216. The output 215 has a re-biased OFF level because the output will only be pulled down to Vth due to the additional NMOS transistor 216.

Logic on Re-Biasing for Reduced gₘ.

A transistor has a transconductance that depends on how strong the control voltage is, and the dimensions of the transistor. A transistor acts like a non-ideal switch. When it is ‘on’ it can be viewed as a wire with a particular resistance R=1/gₘ. The higher gₘ is, the lower R is, and the better switch it is. For the circuits being described a high resistance R is better, and so it can be beneficial to reduce the gₘ. Power consumption, size and/or control voltage can be reduced as a result.

In the illustrated example, the UP/DN signals from the phase detector drive NMOS and PMOS transistors in the thermometer filter. A simplified model of a section of the thermometer filter is shown in FIG. 5, consisting of a transistor 230, and associated capacitance at 232. When the transistor 230 is conducting, an equivalent circuit model is indicated at 234, where the transistor 230 is represented by a resistor with value 1/gₘ 235, with the capacitance 232 as before.

The circuit 234 can be recognized as a low-pass filter with bandwidth gₘ/C. A common goal in PLL/DLL design is to manipulate (and normally reduce) this bandwidth efficiently. One way to reduce the filter bandwidth is to reduce gₘ. This can be accomplished by decreasing the width/length ratio of the transistor (which costs area and power), or by reducing the ON voltage level. To easily reduce the ON voltage level (e.g. VDD to VDD-Vth), the UP/DN control voltages can be passed through NMOS transistors which only pass voltages up to VDD-Vth. In a similar manner, a PMOS pass-transistor can be used to limit the ON voltages to Vth in active-low signals. Use of these pass-transistors to limit the ON voltage is shown in FIG. 6.

In FIG. 6, generally indicated at 240 is a simple circuit for limiting the ON voltage to VDD-Vth. Shown is a single NMOS transistor that has its source connected to receive the dn output of the phase detector (or the up output), and has its gate connected to VDD. The output on the drain is limited to VDD-Vth.

Generally indicated at 242 is a simple circuit for limiting the ON voltage to Vth for active low signals. Shown is a single PMOS transistor that has its source connected to receive the active low dn output of the phase detector (or the up output), and has its gate connected to VSS. The output on the drain is limited to Vth.

As described above, there is a competition between the two sets of tri-state buffers 70,74 to establish the transition point where the output 68 transitions from zeros to ones with typically one or more analog outputs in the transition region. How quickly these buffers (or inverters) operate translate into the response time, and therefore the bandwidth, of the thermometer filter. Re-biasing the logic on state as described above serves to slow down the rate at which the buffer states are propagated through the sets of tri-state buffers. This makes the tri-state buffers slower to operate, lowering the filter bandwidth. A similar effect can be achieved in the inverter based implementation.

Filtering Effects of Conditioning Hardware

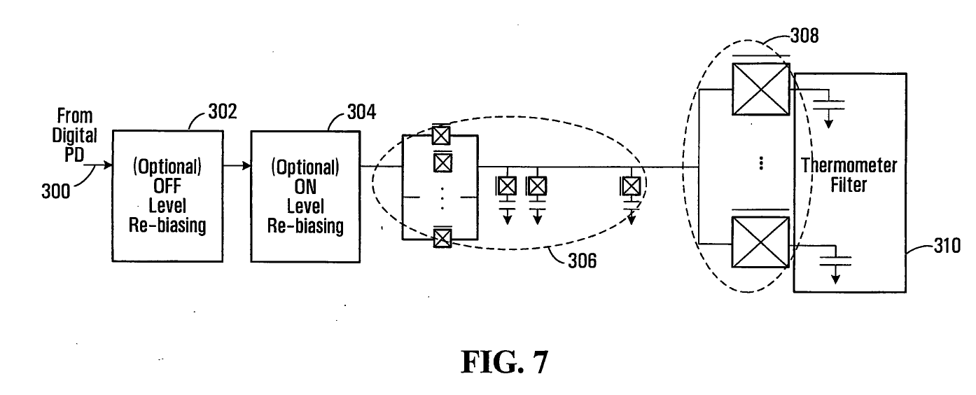

The primary filtering of the system is achieved by the cascaded gₘ/C buffer (or inverter) stages within the thermometer filter. The re-biasing circuits described above are optional, where the interconnection of these components is described in FIG. 7. The optional OFF level re-biasing circuit 302, is useful for dead-zone reduction, and can be composed of the circuits 210 or 205 depending on whether the output is active high or low, respectively. Other implementations of the OFF level re-biasing circuit are also possible. The goal of the optional logic ON level re-biasing 304, as mentioned, is to reduce the speed of the main thermometer filter by reducing the value of gₘ inside the buffer (or inverter) stages. This re-biasing can be performed with transistors in a configuration such as in 240 and 242, or in any number of conventional ways.

It is noted that the various transistors in the re-biasing circuits can be treated as resistive elements (R), and that there are parasitic capacitances within these circuits (e.g. on nodes 205, 210, etc.). The output of the biasing circuits ultimately drive the control inputs of the thermometer filter's tri-state buffers (or inverters), which also have an associated parasitic capacitance. Together, the effective resistance and capacitance perform a low-pass filtering of the phase/frequency-detector outputs before they reach the primary thermometer filter.

The level of pre-filtering performed by these circuits can be manipulated by adjusting the various transistor sizes. In another embodiment, further pre-filtering is done using an adjustable filter network 306 (such as an RC filter network), before the controls reach the main thermometer filter. At the thermometer filter, the signals are exposed to the relatively large parasitic capacitance of the tri-state buffers/inverters. Rather than drive these loads with full-swing digital UP/DN pulses, which would waste significant power, the pre-filtering limits signal swing (reducing power), and takes advantage of the parasitic capacitances to add higher order poles and reduce the loop response at higher frequencies, thus lowering reference feed-through and other noise contributions.

Changing R and/or C of the RC circuit can improve the output frequency characteristics. In particular, noise can be filtered out at the reference frequency, i.e., reference spurs can be lowered. Advantageously, by using the techniques described above, R and C can be set on an application specific basis to tune the overall circuit to have the desired RC characteristics and the desired output frequency characteristics.

Steering Logic to Save Power

In the thermometer filter, only a few control nets are under analog control at any time. The others are digitally locked at 1 or 0. Because of the characteristics of the thermometer code, the filter can be partitioned into arbitrarily small sections and, with simple logic, the control steered to only the analog section of the thermometer filter which needs it. This reduces the capacitance on the UP/DN control nets, and depending on whether/how the pre-filtering is used, can save significant power. This steering logic is particularly helpful if a large number of thermometer stages is used, and/or they are being driven directly by a digital phase-detector. Optional steering logic is shown in FIG. 7.

FIG. 7 shows a number of optional features connected before the thermometer filter 310. These features process the up/down signals 300 from the phase detector prior to their reaching the thermometer filter 310, and include optional OFF level re-biasing 302, optional ON level re-biasing 304, optional extra variable RC filtering 306, and optional steering logic 308. Any appropriate number of these features can be included in a given implementation.

Example circuits for logic OFF and logic ON re-biasing have been presented above. More generally, any circuit that can achieve these functions can be employed.

For the optional extra variable RC filtering 306, in one example, resistive transmission gates can be used to implement adjustable R. More generally, any appropriate circuit that can achieve the adjustable R can be employed. Similarly, wide transmission gates can be used to implement switchable capacitance. More generally, any appropriate circuit that can achieve the additional capacitance can be employed.

Extra Capacitance

As discussed above, the transistors in the tri-state buffers/inverters contribute the effective resistance in the primary RC filter. The bandwidth of the overall circuit can be adjusted by putting more or less capacitance on the nets and/or by turning more or fewer transistors on to change the resistance in the RC circuit.

Referring again to FIG. 2A, a filter is shown connected at 180 to each of the stages. This might contain extra resistance and/or capacitance which then contributes to the overall RC circuit and effects the bandwidth and stability of the device. In DLLs, the filter might only be capacitance, whereas it is preferably a resistance and capacitance in PLL configurations for stabilization. In either case, both R and C can be selected on an implementation specific basis to achieve the desired loop characteristics, or can be made adjustable using a switched resistance/capacitance network such as in 306 of FIG. 7.

Stabilizing the Digital Values

Once the circuit of FIG. 1 or 2 is in lock, or very close to perfect lock, there will be no up or down pulses generated and the capacitance on the control nets will hold information so long as everything is off. However, in some implementations, there may be background noise such as cross talk, interference, leakage, etc. that may have an effect upon these capacitances over time and change the stored information. In another embodiment of the invention, at least some of the logic 0s and logic 1s, once they obtain such a state, are held in a manner that they are no longer susceptible to background noise. The remaining capacitances are allowed to fluctuate, in particular those that are holding non-digital states. A detailed example of how the logic 0 and logic 1 states can be maintained is provided below. Due to the fact that a thermometer code is being implemented, with an analog transition region, it is possible for the state of one stage to be deduced from its neighbours. For example, in the tri-state buffer based solution, a state that has a “zero” to its left and “zero” to its right must necessarily also have a zero state. Similarly, a stage with a “one” to its left and a “one” to its right must also similarly have a one state.

The thermometer filter state can potentially be made more stable by connecting those voltages which have already hit their limit to VDD, VSS, or to other ON/OFF reference levels as appropriate. This removes their susceptibility to leakage, and lowers their response to coupled noise sources.

In such implementations the few analog control nets are allowed to fluctuate, while locking all others at their digital extremes. Because of the thermometer coding, simple logic at each position can look at its neighbors to determine whether it should be locked to a digital value, or be left free to undergo analog control. The following is an example of a thermometer filter state for an inverter-based implementation:

| | | | | | | | | | |
|---|---|---|---|---|---|---|---|---|---|
| 1 | 0 | 1 | 0 | 1 | .2 | 0 | 1 | 0 | 1 |
| | A | | | | B | | | | |

If both neighbours agree, then a particular ‘bit’ should be locked to the opposite value. If they disagree, then it is to undergo analog control, or is on the verge of being under analog control. For example, if logic at position A notices that both its neighbours are 1, it should be tied to 0. If they are both 0, it should be tied to 1. At position B, the values to the left and right do not match, and so the control net is not digitally tied-off.

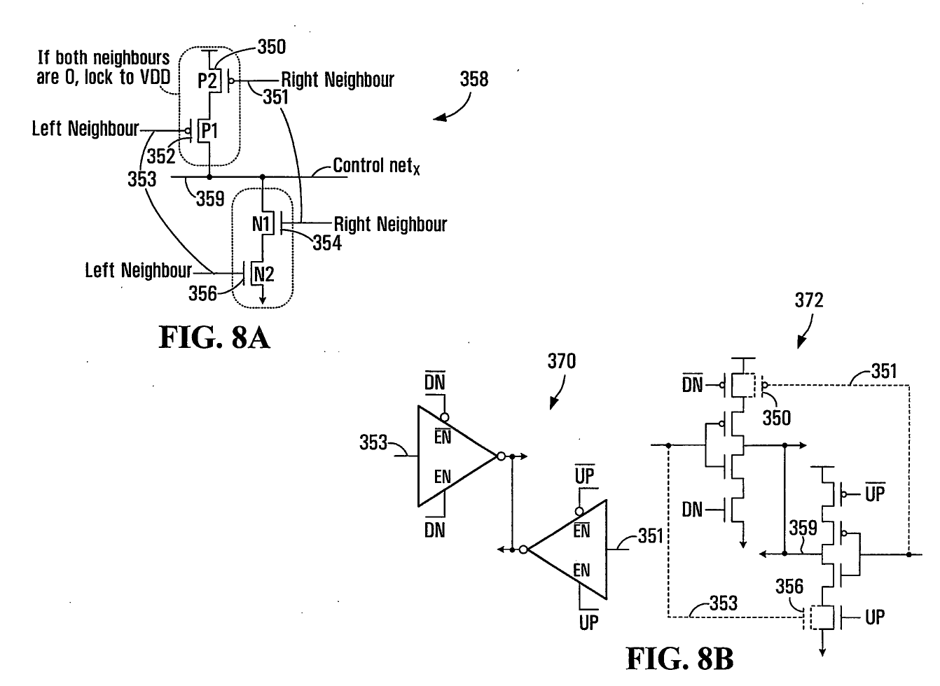

Referring now to FIG. 8A, generally indicated at 358 is a circuit for locking in a digital state for a control net 359 based on neighbour state information. Such a circuit can be implemented for any of the control nets in a thermometer filter, where end points are tied off to the logic 0 or 1 constant which it finds as its neighbour at the end of the line. The control net 359 is influenced by the right neighbour control net 351 through PMOS transistor 350 and the left neighbour control net 353 through PMOS transistor 352. Transistor 350 is connected to VDD. If both neighbours are “0”, then the path through the two transistors 350,352 connects the control net to VDD and locks in the state.

Similarly, the control net 359 is influenced by the right neighbour control net 351 through NMOS transistor 354 and by the left neighbour control net 353 through NMOS transistor 356. Transistor 356 is connected to VSS. If both neighbours are “1”, then the path through the two transistors 354,356 connects the control net to VSS and locks in the state.

It is readily apparent how the circuit can be adjusted through appropriate selection of NMOS, PMOS transistors to process either the inverter based states which alternate in the non-analog region, and the tri-state buffer based states that do not alternate in the non-analog region.

More generally, logic to perform this check and tie-off can be implemented in any suitable manner. A specific example that employs MOS transistors (N1 354, N2 356, P1 352, P2 350) has been described with reference to FIG. 8A. Advantageously, one half of the tie-off hardware can be eliminated by recognizing that in either the buffer of inverter configuration of the thermometer filter, each stage is already looking at its neighbours. This is shown for the inverter configuration, for example, in FIG. 8B which shows the gate-level view of a stage of the thermometer filter generally indicated at 370, in addition to the transistor level implementation generally indicated at 372 with additional circuitry for performing the neighbour comparisons indicated in using dotted lines. It can be seen that as part of the natural inverter configuration, transistors N1 and P1 are already connected as needed. To implement the additional logic of 358 therefore only requires the addition of two more ‘bypass’ transistors (N2 356 and P2 350), that tie-off the control net when both neighbours agree.

Saving State

Another embodiment of the invention provides a mechanism for saving the state of the circuit when it is turned off. More particularly, preferably each of the logic 0s and logic 1s is saved, and for any analog states, these are rounded off to the nearest logic 1 or logic 0 state and saved. In this manner, should the circuit be turned off and then subsequently turned on again, the delay that would be experienced as a result of completely re-locking would not be incurred. Rather, there would only be the short amount of time necessary to fine tune the analog states. FIG. 2A shows a particular mechanism for achieving this. Shown is a set of latch circuits 160 that have a control input 162 that when activated will save the state of each of the outputs 68. Assuming this control input 162 is activated prior to turning off the circuit, the digital state of the circuit will be stored in the latches 160. When the circuit is then turned on again, the delay line 142 will operate in accordance with the stored digital values until such time as the control input 162 is de-activated after which time they will be allowed to drift to their more precise states.

In the above-described embodiments, latches are provided to store the state of the output of the thermometer filter such that if the overall circuit is turned off and then on again, the state can be maintained. One way to save and hold this approximate state would be to enable a latch on each stage of the control string. This, however, adds at least 6 transistors/stage. In another embodiment, recognition is made of the fact that the thermometer code output is completely defined by only a few states in the transition region between logic 0 and logic 1 for tri-state buffer implementations, similar conclusions being possible for inverter based implementations. This is because all bits to the left of the transition region will necessarily be logic 0, and bits to the right of the transition region will be necessarily logic 1. Thus knowledge of where the transition takes place is enough to store most of the state.

The digital stabilization method described above inter-locks each control net that is over a bit distance away from the analog region of the control string. To save all the bits of the string, it is therefore sufficient to latch only the values that are not digitally stabilized, which in turn locks the rest of the line. To permit operation again, the latches in the analog section are disabled, and the system recovers from the closest digital approximation of the lock state. Advantageously, the same circuitry that can be used to decide where to switch in shared filter sections as described below (shared filter sections and state memory) can be used to decide where to switch in the circuits that will remember the state. For the shared filter implementations, those bits near the analog region of the control string, are instead tied to the shared filter sections. In this manner, rather than using 60 latches in a 60 state circuit for example, as few as three latches might be used to remember the entire state with the exception of the analog states which are rounded off to a logic 1 or 0.

While an example of a circuit/method for saving state has been described that relies on the digital stabilization and shared filter aspects, it is to be understood that the state saving aspect could be implemented independent of those aspects, in an entirely different manner that either maintains the state of the entire control string, or a reduced portion of the state from which the entire state (at least the non-analog portion) can be deduced.

Simplifying Driver Hardware in Thermometer filter

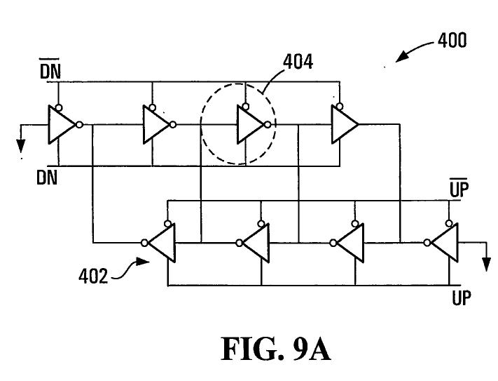

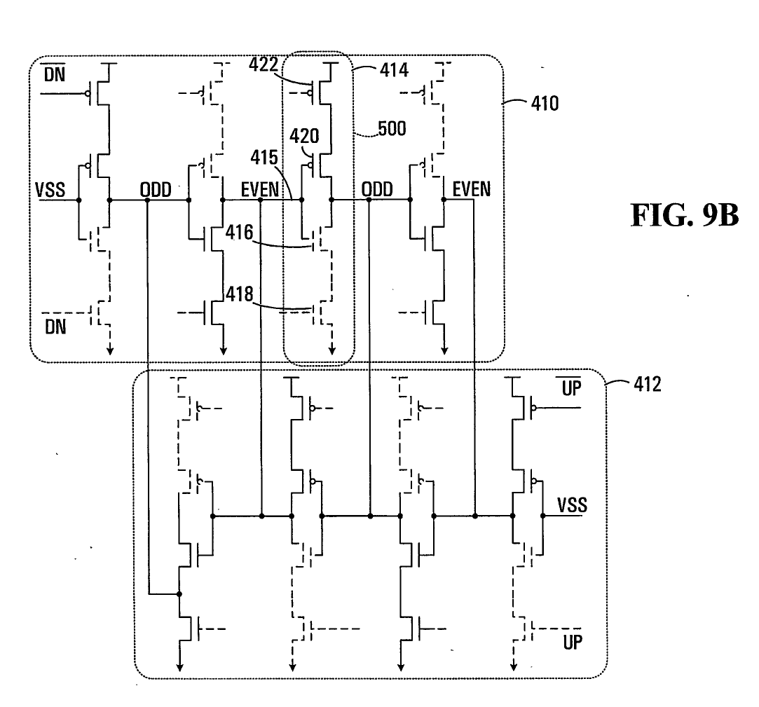

There are many well-known circuits for implementing driver elements such as tri-state buffers and inverters. The typical circuit for a buffer has the ability to drive an input logic 1 to output a logic 1 and similarly drive a logic 0 input to output a logic 0. However, in the mixed-signal thermometer filter, the entire functionality does not necessarily need to be implemented. This is because the buffers in the up path only ever need to output logic 0s, to reduce delay, and the inverters in the down path only need to output logic 1s, to increase delay. A similar argument can be made in the case of the inverter configuration, where inverters in the up path are only responsible for changes that ultimately decrease delay, and those in the down path are responsible for changes that increase delay. This can be taken advantage of to reduce the complexity of the buffer or inverter circuits such that only partial functionality is implemented. A driver element that only has the functionality to implement one transition (be it low to high or high to low) will be referred to herein as a single transition driver element. FIG. 9A shows a block diagram representation of a 4-“bit” thermometer filter, in this case an inverter based implementation, with the two sets of inverters generally indicated at 400,402, the first set 400 being driven by the dn signal and the second set 402 being driven by the up signal. A particular inverter in the first set is indicated at 404.

FIG. 9B shows a transistor-level 4-“bit” representation of a thermometer filter, in which half of the transistors (those shown as dotted lines) can be removed. In the modified design, all of the transistors in the top delay line which charge EVEN nets and discharge ODD nets are eliminated. The same approach can be used to eliminate all of the transistors in the bottom delay line which would charge ODD nets, and discharge EVEN nets.

The thermometer filter of FIG. 9B includes transistor circuit 410 for the first set of inverters, and transistor circuit 412 for the second set of inverters. The transistors for the particular inverter 404 of FIG. 9A are indicated at 414 for an example implementation in which the input to the inverter is indicated at 415, and this is connected through NMOS transistors 416,418 to VSS. The input is also connected through PMOS transistors 420,422 to VDD. The dn signal is connected to the gate of transistor 418 and the inverted dn signal is connected to the gate of transistor 422. For the particular stage 414, this should only ever be responsible for charging, and as such, the transistors 416,418 can be omitted to simplify the circuit. Similarly, transistors can be omitted from each other inverter in recognition of the fact that only one of charging or discharging will ever be required in any given stage.

In such an implementation, since the top line does not have the ability to charge an EVEN net, if the control string, for example, were: 0 1 0 1 0.4 and the full logic 1s started to degrade, only the occurrence of UP pulses could reconstruct them towards full logic levels as desired. The digital stabilization method, referred to previously, can be employed to prevent this degradation, but if it, or comparable methods, are not used, it may be beneficial to leave these transistors in so that either UP or DN pulses will reconstruct all stable digital values.

FIG. 9B shows an example of a single transition inverter. A similar approach can be used to design a single transition buffer.

Sharing Filter Sections and State Memory

Referring again to FIG. 2A, an “extra filter” is shown connected at 180 to each of the stages. The capacitance and/or resistance of the filter contributes to the overall RC circuit and effects the bandwidth and stability of the device.

Such an extra filter is only actually required or of benefit for the stages that are in the non-digital state i.e., for stages that are generating a logic 0 or logic 1, the output is static and the extra filtering is not needed. Rather, the only states that benefit from the extra resistance and/or capacitance (or active filter) are those that are in an analog state. According to another embodiment of the invention, a reduced number of “extra filter cells” 180 is provided that is switched in or out of a given stage in accordance with its logic 0, logic 1, or analog state. In a preferred embodiment, three such filter cells are provided that are switched into the transition region of the thermometer code output. Similar circuitry that is used to perform the previously discussed “neighbour analysis” for digital stabilization can be used to determine where the analog controls are, and thus where additional filtering needs to be switched in. Advantageously, in a large circuit, for example one that might have 60 stages, rather than including 60 extra filter cells 180, most of these can be eliminated and replaced with only three filter cells. Since both resistors and capacitors take up a significant amount area in integrated circuits, this can be a very significant saving.

If the analog control voltage in a conventional filter were divided into N ideal sections, each section would require a capacitance 180 of C/N to maintain the same overall loop characteristics.

In the mixed-signal thermometer code, however, only a few stages are ever undergoing analog transitions at a time. All of the other stages are pinned at either 0 or 1, and their filter stages, consisting of a resistor and capacitor R*C/N, are unused. This creates the opportunity to share hardware. In this scenario, we share 3 filter cells (R*C/N) between all N stages of the thermometer filter. Sharing 3 stages is advantageous in practical scenarios since up to 2 control bits may be undergoing analog transitions at any time, and an odd number of stages can be used to prevent problems when switching discharged filters onto charged control nets, and vise-versa. A smaller or larger number of shared filter stages might be appropriate depending on the how many outputs can be analog simultaneously.

In order to determine which control nets to hook-up to a filter stage, the characteristics of the thermometer code are used (as before when determining which bits to digitally tie-off to 1 or 0). Examining an example inverting code,

| | | | | | | | | | |
|---|---|---|---|---|---|---|---|---|---|
| 1 | 0 | 1 | 0 | 1 | .2 | 0 | 1 | 0 | 1, |
| | | | A | B | C | D | E | | |

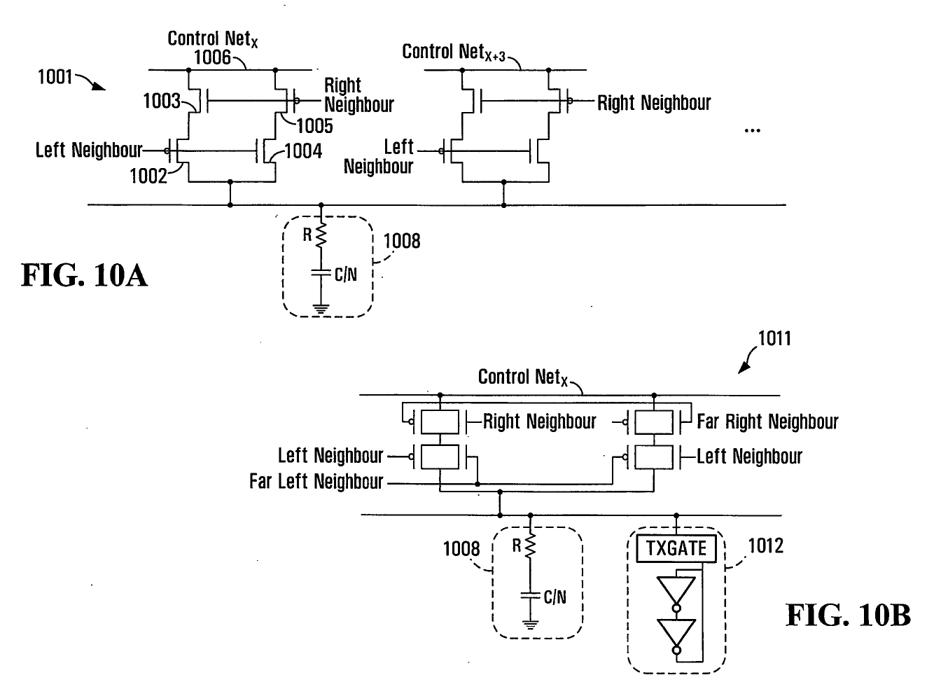

the analog position is found by noting when its' neighbours disagree. In this example, this is strongly true in position C, and weakly true in positions B and D. As such, the control net at C should certainly be connected to a filter stage, since it is in the analog domain, and the control nets at B and D should also be connected, in preparation for when they may enter the analog domain. An example of how to perform the necessary switching is shown in FIG. 10A.

The logic network to connect a particular control net 1006 to a shared analog filter stage 1008 is generally indicated at 1001 of FIG. 10A. NMOS transistors conduct when their gate is a logic 1, and PMOS transistors conduct when their gate is a logic 0. As such, the branch of the logic network 1001 which consists of PMOS 1002 and NMOS 1003 will connect 1006 to filter stage 1008 when the neighbours disagree such that left neighbour is 0 and the right neighbour is 1. In a similar manner, if the neighbours disagree such that the left neighbour is 1, and the right neighbour of 0, then the net 1006 is connected through NMOS 1004 and PMOS 1005 to the filter stage 1008.

Using PMOS and NMOS transistors in this switching configuration, though logically correct, may perform poorly. Since PMOS switches are poor at passing low voltages and NMOS switches are poor at passing high voltages, using them in series means the switch only works well at mid-range levels. A solution to this problem is to use transmission gates (with complementary NMOS and PMOS transistors in parallel), rather than use single pass transistors. To use a transmission gate structure, however, the control of the complementary transistor in the transmission gate must be inverted. Since the control inputs in this case are potentially analog, there are adverse effects to using conventional inverters. Instead, it can be noted that by virtue of the inverting thermometer code, there is already access to the inverted versions of the left (namely from the inverter two to the left) and right neighbours (namely from the inverter two to the right). In FIG. 10B, complementary NMOS and PMOS transistors are inserted into the switch logic to form transmission gates, and then fed using these inverted signals as the control inputs. As a result, the logic generally indicated at 1011, performs the same function as that in 1001, but with improved results.

Rather than use fixed values for R and C/N in the shared filter 1008, it is often desirable to make these adjustable. The effective value of R can be modified by changing the sizes of the switches in the logic network, or by implementing R with active devices. Similarly, C/N can be made using a varactor, switched capacitances, or a combination. One potential method for implementing these variations is as was done in 306 of FIG. 7. Finally, the shared filter section 1008 can be made using most other active or passive filtering techniques.

As previously mentioned, to save the state of the entire control string, it is sufficient to save only those control “bits” which are in the analog domain. These values have already been isolated by the aforementioned logic 1011, and attached to the shared filter sections 1008. By latching only these values with circuits such as generally indicated at 1012, it is possible to use only 3 latches to save the entire state, eliminating the latches 160 in FIG. 2A. It should be noted that there are many conventional methods to implement a latch, many of which would be appropriate here.

The example implementations of FIGS. 1 and 2 show a mixed-signal thermometer filter in the context of DLL de-skew circuits. The mixed-signal thermometer filter has other applications. A few specific examples are given below, but this is not intended to be a comprehensive list.

Phase Locked Loop

A phase locked loop works to match the phase of its outputs. If the phases are consistently matched, the frequencies are also matched. Advantageously, this makes it easy to generate an arbitrary multiple of the clock frequency. Typically PLL implementations may consume less power than DLL configurations.

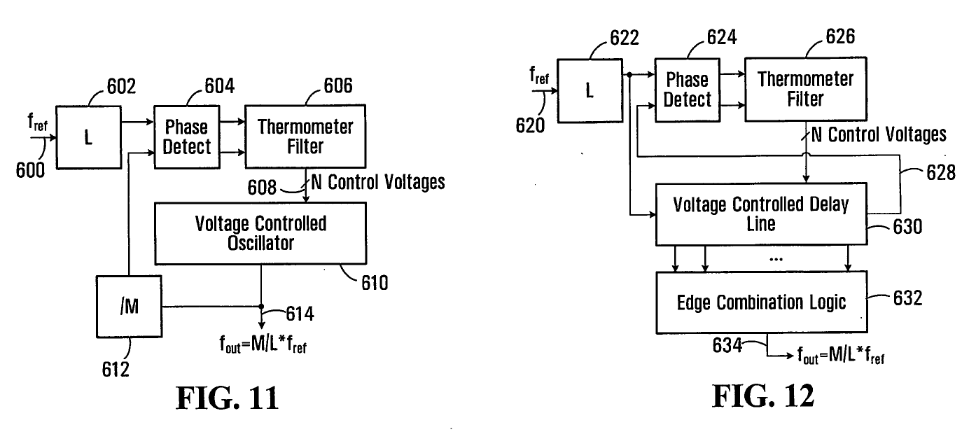

A block diagram of circuit that employs the mixed-signal thermometer filter in a PLL synthesizer configuration is shown in FIG. 11. A reference input 600 having frequency f_{ref} is input to a divide by L function 602 the output of which is input to the phase detector 604. The phase detector 604 has up/down outputs connected to a thermometer filter 606. The thermometer filter 606 produces N control voltages 608 that drive a voltage controlled oscillator 610, the control voltages 608 including mainly digital values, and several analog values, depending upon the state of lock. The output signal 614 is also passed through a divide by M function 612 that is in turn connected to the feedback input of the phase detector 604. The result is that the frequency at the output of the voltage controlled oscillator 610 is locked to f_{ref} M/L. Not all implementations necessarily include both the divide by M and the divide by L if that flexibility is not a requirement. Most conventional methods of VCO 610 construction can be extended to appropriately accept the mixed-signal thermometer code. One such manner is to use a ring oscillator and use the same techniques as presented for the DLL configurations to adjust loading or current, and therefore regulate delay and oscillation frequency. Another approach, which typically yields higher quality outputs, is to use an LC based oscillator with the C being adjusted through either an array of varactors or switched capacitance tuning.

Delay Locked Loop

A DLL does not have an oscillator. Instead it controls a delay line to match a reference period. It can extract the signal at various phases and logically combine them to create multiples of the reference clock.

A block diagram of a circuit that employs the mixed-signal thermometer filter in a DLL synthesizer configuration is shown in FIG. 12. A reference input 620 having frequency f_{ref} is input to a divide by L function 622 the output of which is input to the phase detector 624. The phase detector 624 has up/down outputs connected to a thermometer filter 626. The thermometer filter 626 produces N control voltages that drive a voltage controlled delay line 630, the control voltages including mainly digital values, and several analog values, depending upon the state of lock. The output of the divide by L function 622 is also input to the voltage controlled delay line. Each of the control voltages controls a plurality of delay elements in the voltage controlled delay line. The voltage controlled delay line 630 needs to be capable of processing both digital inputs and analog inputs. Particular examples of such a delay line have been given earlier. The output 628 of the voltage controlled delay line signal 614 is connected to the feedback input of the phase detector 624. Phases of the signal, at various points along the voltage controlled delay line 630 are tapped off and input to edge combination logic 632. If M equally spaced phases are taped off, then the edge combination logic can be used to produce an output signal with a frequency fₒᵤₜ=M/L f_{ref}.

DLL De-Skew Circuits

In most cases, it is desirable that any circuits receiving a related synchronization (e.g. clock) signal, receive it simultaneously. A DLL can be used in different configurations to make this task easier.

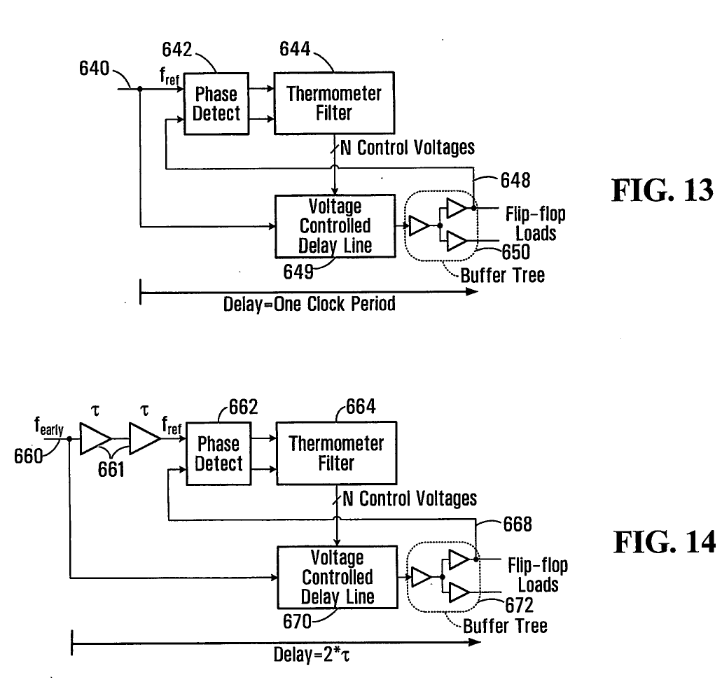

A block diagram of a circuit that employs the mixed-signal thermometer filter in a DLL de-skew circuit is shown in FIG. 13, this being a generalization of the embodiments of FIGS. 1 and 2. A reference input 640 having frequency f_{ref} is input to the phase detector 642. The phase detector 642 has up/down outputs connected to a thermometer filter 644. The thermometer filter 644 produces N control voltages that drive a voltage controlled delay line 649, the control voltages including mainly digital values, and several analog values, depending upon the state of lock. The output signal of the voltage controlled delay line 649 is input to a buffer tree 650. One output 648 of the buffer tree 650 is connected to the feedback input of the phase detector 642. This circuit forces the delay from the reference port to the buffer tree output 648 to match one clock period. In the scenario of FIG. 13 (and later FIG. 14), the buffer tree 650 is designed to be symmetric, and in a localized region of the circuit. Given these conditions it can be designed so that the difference in arrival times between the various outputs of the tree is negligible. As such, all clocked circuits at the output of the tree receive the synchronization signal simultaneously, and when locked, exactly one clock period from when the signal arrived at the input 640. Because the delay between input and output is tuned to exactly one clock period, a number of these circuits (FIG. 13) can be arranged in a hierarchical fashion, and provided the inputs 640 to each are controlled to arrive simultaneously, the outputs to a much larger number of circuits, can also be controlled to arrive simultaneously. Because of the ability to control the timing accurately to a large number of loads, provided the timing is accurately controlled to (a much smaller) input load, the circuit of FIG. 13 is also called a “Period Delay Buffer”, or sometimes a “Zero Delay Buffer”

A block diagram of a circuit that employs the mixed-signal thermometer filter in another DLL de-skew circuit is shown in FIG. 14. A reference input 660 having frequency f_{ref} is input to two buffers 661 each introducing a delay of τ. The output of the two buffers 661 is connected as one input to the phase detector 662. The phase detector 662 has up/down outputs connected to a thermometer filter 664. The thermometer filter 664 produces N control voltages that drive a voltage controlled delay line 670, the control voltages including mainly digital values, and several analog values, depending upon the state of lock. The output signal of the voltage controlled delay line 670 is input to a buffer tree 672. One output 668 of the buffer tree 672 is connected to the feedback input of the phase detector 662. This circuit forces the delay from the input port 660 to the buffer tree output 668 to match the insertion delay of 2*τor more generally, whatever the insertion delay is.

While the illustrated embodiments have shown four control cells, more generally, any appropriate number of control cells may be implemented. Typical range might be for example from between two and 1024 control cells, but larger numbers are not to be excluded.

Also, the number of delay stages to be included is an implementation specific consideration. The two examples shown have specifically illustrated two delay stages. However, any number of delay stages are contemplated.

In the above-described embodiment employing latches to maintain the state, these latches can be implemented using any appropriate technology. This might for example consist of conventional CMOS techniques, or using two back to back tri-state buffers with slightly offset control signal timing.

A different approach to store the digital representation of the control nets is to make use of the back to back tri-states which already exist in the thermometer filter of FIG. 1. By appropriately sectioning the UP/DN control signals and selectively turning on back-to-back drivers, the control nets will go to and store values close to their nearest digital representation. Though this approach adds very little circuitry to the design, it decreases the precision of the saved values since each pair of control nets are forced to complementary values.

Though in some applications the natural speed of the tri-state buffers coupled with the parasitic capacitance of the wiring and gate-capacitance of the switches will be slow enough to provide necessary filtering, it may be necessary to decrease the drive strength and/or increase the capacitance to slow the charge and discharge times to acceptable values. This can be accomplished by using degenerate transistor sizing (where Width/Length ratios are <1) and/or by adding extra capacitance to the control nets in the form of standard cell loads. Examples of how to achieve this have been given above.

It is possible to enhance the variable delay line by modifying the drivers (inverters in the illustrated example) to also have a variable drive strength or delay using any method conventional or otherwise. The control of these drivers can then be controlled using another control loop. Such a control loop may be either analog, digital, or use the same thermometer filter as described herein. If using this circuit in any configuration where the thermometer filter is used for fine control, initial rough lock can be performed with the control nets initialized to an intermediate value between the two extremes. This can be done with simple control logic on the UP/DN signal lines that divides the thermometer filter into two halves and on reset, asserts the UP control to one half and the DN control to the other half.

The phase-detector may be constructed such that it can recognize a false-lock condition and provide the UP/DN control signals as appropriate.

The thermometer filter can be used independently from the mixed-signal adjustable delay element in appropriate applications.

The mixed-signal switch transistors may have an attached external capacitance in addition to its parasitic source capacitance. This will increase the range at the cost of lowered digital precision.

The sizing of the switch transistors can be optimized to produce specific loop and filter characteristics.

The sizing of the effective delay capacitances or switch transistors can be manipulated to produce non-linear delay characteristics versus control word values.

The delay line can be implemented in various other forms, including but not limited to those described. For example, the delay line 66 can be implemented using differential circuitry.

The thermometer filter can be implemented using any logic style (e.g. CML, MCML, Dynamic logic, NMOS, ECL, etc . . . ) or process (discrete, Si, SiGe, Ge, etc . . . ).

Similarly, the delay line can be implemented using any logic style (e.g. CML, MCML, Dynamic logic, NMOS, ECL, etc . . . ) or process (discrete, Si, SiGe, Ge, etc . . . ).

In another embodiment, the thermometer filter can be used to control delay lines in a pair-wise Vernier type configuration. This configuration is similar to the DLL approach already described in FIG. 12 but employs a second slave delay line, with an extra stage, and shared control signals. Among other places, this configuration is common in high precision time to digital converters.

The thermometer filter can be applied to a voltage controlled oscillator where the control bits/nets are responsible for adjusting the resonance of the oscillator. Added resistance or active circuitry may be placed between the tri-state drivers and delay cells to adjust the frequency response of the loop.

The thermometer filter may also be constructed using conventional asynchronous self-timed circuits rather than using the tri-state delay-line approach presented here. Such an approach would be a straightforward implementation of the method proposed here, but generally suffers from decreased circuit efficiency.

In a PLL configuration, the thermometer filter can be used as a combined demodulator and analog to digital converter. In this scenario the dynamics of the filter can be adjusted to allow the control word to track frequency or phase modulation in a carrier of interest. While tracking, the digital representation of the mixed-signal control word is the thermometer coded result of the modulating input.

In the above-described examples, it is assumed that the phase detector produces two control outputs and that the thermometer filter operates as a function of these control outputs. More generally, the described circuits can be thought of as operating in three different states defined by the control inputs, namely up input active, down input active, and no inputs active. The three states can be otherwise defined.

In another embodiment, the circuits only operate in two states, and as such these can be defined by a single control input. The two states might for example be up input active and down active, but these can be otherwise defined. In a two state implementation, there is no inactive state, and as such, the code is always being driven on one direction or another.

In the described embodiments, the code is driven from left to right or from right to left depending on the control inputs. More generally, since the purpose of the code can be thought of as introducing delay through the delay line, it is not really important the sequence that on mixed-signal outputs get switched to off mixed-signal outputs and vice versa, since the transition of any one mixed-signal output can potentially have the same effect upon the delay in the delay line (assuming the delay elements are identical). Thus, in another implementation, rather than driving the code from two different directions, the code can be driven from one end such that while in one control state, on's are transitioned to off's, and while in another control state, off's are transitioned to on's. Mathematically, this should end up being equivalent to the thermometer filter example, but in which the code is not justified.

The thermometer filters can also be referred to as asynchronous dual mixed signal shift registers where appropriate.

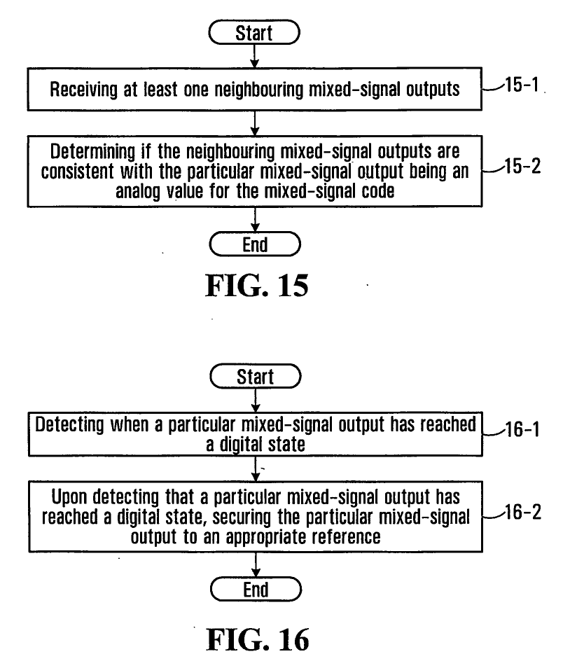

A detailed method of determining which mixed-signal outputs are analog outputs has been described for application to thermometer codes. This method has more general application. Another embodiment of the invention provides a method for dynamically determining if a particular output of a set of mixed-signal outputs representing a mixed signal code is outputting an analog value. The method is summarized in the flowchart of FIG. 15 and involves receiving at least one neighbouring mixed-signal outputs at step 15-1; determining if the neighbouring mixed-signal outputs are consistent with the particular mixed-signal output being an analog value for the mixed-signal code at step 15-2. A particular circuit has been taught above to handle thermometer codes (be they as output by non-inverting driving elements or inverting driving elements). For non-inverting driving elements, the neighbour outputs are consistent with an analog output when they disagree, where as for inverting driving elements, the neighbour outputs are consistent with an analog output when they agree. Other mixed-signal codes may have different criteria.

Having identified the analog outputs, various additional steps can optionally be performed, such as connecting in a shared filter stage to the output, or connecting a shared state maintaining element to the output.

A detailed method of determining which mixed-signal outputs are digital outputs has been described for application to thermometer codes. This method has more general application. Another embodiment of the invention provides a method of processing a set of mixed-signal outputs to identify the digital outputs. The method is summarized in FIG. 16 and involves detecting when a particular mixed-signal output has reached a digital state at step 16-1; upon detecting that a particular mixed-signal output has reached a digital state, securing the particular mixed-signal output to an appropriate reference at step 16-2.

In some embodiments the set of mixed-signal outputs represent a mixed-signal code, and detecting when a particular mixed-signal output has reached a digital state involves receiving at least one neighbouring mixed-signal outputs, and determining if the neighbouring mixed-signal outputs are consistent with the particular mixed-signal output being a digital state for the mixed-signal code.

Numerous modifications and variations of the present invention are possible in light of the above teachings. It is therefore to be understood that within the scope of the appended claims, the invention may be practiced otherwise than as specifically described herein.

1. A circuit comprising:
a plurality of mixed-signal outputs;
a first set of driving elements connected together in sequence each having a respective output connected to a respective one of the mixed-signal outputs, the first set of driving elements having a first driving element and having a last driving element;
a second set of driving elements connected together in sequence each having a respective output connected to a respective one of the mixed signal outputs in an order opposite to an order of connection of the first set of driving elements to the mixed signal outputs, the second set of driving elements having a first driving element and a last driving element;
wherein while in a first control state the first set of driving elements drives each of the mixed-signal outputs towards a respective off state sequentially in a direction from the first driving element of the first set towards the last driving element of the first set such that any mixed-signal output that is driven only partially towards its respective off state maintains an analog value; and
wherein while in a second control state the second set of driving elements drives each of the mixed-signal outputs towards a respective on state sequentially in a direction from the first driving element of the second set towards the last driving element of the second set such that any mixed-signal output that is driven only partially towards its respective on state maintains an analog value;
wherein while in a third control state each mixed-signal value maintains its respective value.

2. The circuit of claim 1 comprising two control inputs that define the first, second and third control states.

3. The circuit of claim 1 wherein each driving element is a tri-state buffer, and each of the on states are represented by a high voltage, and each of the off states are represented by a low voltage.

4. The circuit of claim 1 wherein each driving element is an inverter, and each of the on states alternate between being represented by a low voltage and a high voltage, and each of the off states alternate between being represented by a high voltage and a low voltage.

5. The circuit of claim 1 further comprising:
a logic on biasing circuit that biases an on voltage of any active high control input to an amount below logic high and/or biases any active low control input to an amount above logic low.

6. The circuit of claim 1 further comprising:
a logic off biasing circuit that biases an off voltage of any active high control input to an amount above logic low and/or biases any active low control input to an amount below logic high.

7. The circuit of claim 1 wherein:
each driving element is a single-transition driving element.

8. The circuit of claim 1 further comprising a tunable filter connected between the control input(s) and the driving elements.

9. The circuit of claim 1 further comprising:
a respective additional filter connected to each of the mixed-signal outputs.

10. The circuit of claim 1 further comprising circuitry to dynamically determine a sub-set of the mixed-signal outputs that include at least those producing analog value outputs.

11. The circuit of claim 10 further comprising:
at least one additional filter;
circuitry that dynamically connects the at least one additional filter to mixed-signal outputs that are outputting analog values.

12. The circuit of claim 11, wherein the at least one filter has at least one dynamically adjustable filter characteristic.

13. The circuit of claim 1 further comprising:
circuitry for detecting when a particular mixed-signal output has reached a digital state, and for dynamically securing the particular mixed-signal output to an appropriate reference upon making such a detection.

14. The circuit of claim 1 further comprising:
circuitry for maintaining an approximate state of the mixed-signal outputs upon power down or idle modes of the circuit.

15. The circuit of claim 10 further comprising:
at least one state maintaining element for maintaining an approximate state of the mixed-signal outputs upon power down or idle modes of the circuit;
circuitry to dynamically connect the at least one state maintaining element to the mixed-signal outputs determined to be outputting analog values.

16. The circuit of claim 14 wherein the circuitry for maintaining the approximate state of the mixed signal-outputs which maintains a reduced number of states from which the entire approximate state can be deduced.

17. The circuit of claim 1 adapted to receive at least one control input, the circuit further comprising steering logic for directing signals received on the at least one control input to a subset of the driving elements that are generating analog values.

18. The circuit of claim 1 further comprising a delay line comprising at least one delay element, wherein each mixed-signal output controls how much delay such elements introduce into the delay line.

19. The circuit of claim 1 further comprising an LC oscillator, wherein each mixed-signal output is used to tune capacitance of the LC oscillator.

20. A delay locked loop synchronization circuit comprising the circuit of claim 1.

21. A phase locked loop synchronization circuit comprising the circuit of claim 1.

22. A clock de-skew circuit comprising the circuit of claim 1.

23. A circuit implemented method comprising:
in a first control state, driving each of a set of mixed-signal outputs towards a respective off state sequentially from a first mixed signal output towards a last mixed-signal output such that any mixed-signal output that is driven only partially towards its respective off state maintains an analog value; and
in a second control state, driving the mixed-signal outputs towards a respective on state sequentially from the last mixed-signal output towards the first mixed-signal output such that any mixed-signal output that is driven only partially towards its respective on state maintains an analog value.

24. The circuit implemented method of claim 23 further comprising dynamically determining a subset of the set of mixed-signal outputs including at least those that are outputting an analog value.

25. The circuit implemented method of claim 24 wherein dynamically determining which of the set of mixed-signal outputs are outputting an analog value comprises:
for each of at least one particular mixed-signal output:
receiving at least one neighbouring mixed-signal outputs;
determining the mixed-signal output is analog if the neighbouring mixed-signal output(s) are consistent with the particular mixed-signal output being an analog value for a mixed-signal thermometer code.

26. The circuit implemented method of claim 25 further comprising:
dynamically connecting at least one additional filter to the mixed-signal outputs that are outputting analog values.

27. The circuit implemented method of claim 25 further comprising maintaining a respective state for each of the mixed-signal outputs that are outputting analog values.

28. The circuit implemented method of claim 23 further comprising:
detecting when a particular mixed-signal output has reached a digital state;
upon detecting that a particular mixed-signal output has reached a digital state, securing the particular mixed-signal output to an appropriate reference.

29. The circuit implemented method of claim 28 wherein detecting when a particular mixed-signal output has reached a digital state comprises:
receiving at least one neighbouring mixed-signal outputs; determining if the neighbouring mixed-signal outputs are consistent with the particular mixed-signal output being a digital state for a thermometer code.

30. The circuit implemented method of claim 23 further comprising:
receiving at least one control input;
producing at least one biased control input by biasing an on voltage of any active high control input to an amount below logic high and/or biasing any active low control input to an amount above logic; and
the control state being determined by the at least one biased control input.

31. The circuit implemented method of claim 23 further comprising:
receiving at least one control input;
producing at least one biased control input by biasing an off voltage of any active high control input to an amount above logic low and/or biasing any active low control input to an amount below logic high; and
the control state being determined by the at least one biased control input.

32. The circuit implemented method of claim 23 further comprising:
controlling an amount of delay introduced by a respective at least one delay element in a delay line with each of the mixed-signal outputs.

33. A circuit comprising:
at least one control input defining at least a first control state and a second control state;
a plurality of mixed-signal outputs each characterized by a respective on state, a respective off state, and a respective analog range;
a set of circuit elements connected to cause sequential transitions of any mixed-signal output that is in a respective off state or in the respective analog range towards a respective on state during a first control state, and to cause sequential transitions of any mixed-signal output that is in a respective on state or in the respective analog range towards a respective off state during a second control state.

34. The circuit of claim 33 wherein the on states are all logic high and the off states are all logic low.

35. The circuit of claim 33 wherein the on states alternate between being logic high and logic low, and the off states alternate between being logic low and logic high.

36. A method for dynamically determining if a particular output of a set of mixed-signal outputs representing a mixed signal code is outputting an analog value, the method comprising:
receiving at least one neighbouring mixed-signal outputs;
determining if the neighbouring mixed-signal outputs are consistent with the particular mixed-signal output being an analog value for the mixed-signal code.

37. The method of claim 36 wherein the mixed-signal code is a thermometer code.

38. The method of claim 36 further comprising:
dynamically connecting at least one additional capacitance or filter stage to the mixed-signal outputs that are outputting analog values.

39. The method of claim 36 further maintaining a respective state for each of the mixed-signal outputs that are outputting analog values.

40. A method for processing a set of mixed-signal outputs, the method comprising:
detecting when a particular mixed-signal output has reached a digital state;
upon detecting that a particular mixed-signal output has reached a digital state, securing the particular mixed-signal output to an appropriate reference.

41. The method of claim 40 wherein the set of mixed-signal outputs represent a mixed-signal code, and wherein detecting when a particular mixed-signal output has reached a digital state comprises:
receiving at least one neighbouring mixed-signal outputs;
determining if the neighbouring mixed-signal outputs are consistent with the particular mixed-signal output being a digital state for the mixed-signal code.

42. (canceled)

43. (canceled)

44. (canceled)

45. (canceled)

46. (canceled)

47. (canceled)

48. (canceled)

49. (canceled)

50. (canceled)
